(19) United States
(12) Patent Application Publication
(10) Pub. No.: US 2017/0190309 A1
(43) Pub. Date: Jul. 6, 2017

(54) VEHICLE PART FOR THE EXTERIOR AREA OF A MOTOR VEHICLE, AND MOTOR VEHICLE

(71) Applicant: BROSE FAHRZEUGTEILE GMBH & CO. KOMMANDITGESELLSCHAFT, BAMBERG, BAMBERG (DE)

(72) Inventors: BERND HERTHAN, MICHELAU (DE); KARL SCHNEIDER, BESIGHEIM (DE)

(21) Appl. No.: 15/313,611

(22) PCT Filed: May 21, 2015
(86) PCT No.: PCT/EP2015/061234

§ 371 Date: Nov. 23, 2016

(30) Foreign Application Priority Data
May 23, 2014 (DE) 10 2014 007 651.2

(51) Int. Cl. B60R 19/48; E05F 15/73; H03K 17/955; B62D 25/10

(52) U.S. Cl. CPC B60R 19/483; B62D 25/105; E05F 15/73; H03K 17/955; E05Y 2400/858; E05Y 2900/546

(57) ABSTRACT

A motor vehicle has a vehicle part that is designed and configured to be mounted in the exterior area of the motor vehicle. The vehicle part includes at least one sensor electrode of a capacitive proximity sensor. The at least one sensor electrode is disposed on a visible side of the vehicle part. The vehicle part is an underrun guard formed from sheet metal.

The invention concerns a vehicle part for the exterior area of a motor vehicle. Furthermore, the invention concerns a motor vehicle.

In modern (motor) vehicles, in particular automobiles, contactlessly measuring (for example capacitive) distance sensors are often used. Said distance sensors are often used in connection with actuating devices that (contactlessly) detect a door opening request of a vehicle user and thereupon displace an associated adjustment part automatically. The adjustment part is most often a vehicle door, in particular a tail gate of the vehicle that is arranged and provided for reversible closing of the trunk (also referred to as a trunk door or trunk lid). In this case the actuating device is in particular arranged to detect the door opening request using an approach by of the vehicle user (as a type of capacitive switch) or a movement of the vehicle user. In the latter case, the measurement signal detected by means of the distance sensor is compared with a stored reference signal in a control and analysis unit. In the event of adequate agreement of the measurement signal with the reference signal, the control and analysis unit enables the door opening request and actuates the vehicle door to open.

The advantage of such a contactless detection of the door opening request is that the vehicle user has both hands available for carrying cargo items (for example a crate of drinks). A foot movement is mostly envisaged here for detection of the door opening request, in particular a step-like foot movement towards the rear bumper of the vehicle (also referred to as a “foot kick”). In order to be able to detect said foot kick with minimal interference, the distance sensor is most often disposed in the lower region of the rear of the vehicle.

In particular, when using capacitive distance sensors, however, metallic objects in the close surroundings of the capacitive sensor electrode can influence the capacitive detection of a displacement. Conventionally, the sensor electrodes of the capacitive distance sensors are disposed at a sufficient distance from such metallic objects (for example are led around said objects in an undulating manner), so that the influence on the measurement signal is negligible. However, the available installation space in the region of the vehicle parts to which the sensor electrodes are to be applied is often small, so that a freely selectable arrangement of the sensor electrodes is not possible or is only possible with relatively high construction costs.

The object of the invention is to simplify the use of capacitive sensor electrodes in a motor vehicle.

This object is achieved in connection with a vehicle part for the exterior area of a (motor) vehicle according to the invention by the features of claim 1. With respect to a motor vehicle, the object is achieved according to the invention by the features of claim 8. Advantageous embodiments and developments of the invention that are partly inventive in themselves are presented in the sub claims and the following description.

The vehicle part according to the invention comprises at least one sensor electrode of a capacitive proximity sensor. In this case, said (at least one) sensor electrode is disposed on a visible side of the vehicle part. The vehicle part is hereby arranged and provided for mounting in the exterior area, i.e. as part of the outer skin of the vehicle.

The visible side means here and below the side of the vehicle part that in the proper installation state in the vehicle forms a part of the exterior (i.e. of the outer region) of the vehicle, i.e. facing outwards and thereby visible to a person present in the surroundings of the vehicle. Accordingly, the surface (or even outer skin) of the vehicle part (or of the vehicle itself) that is visible from the outside of the vehicle is referred to below as the “visible surface”.

The arrangement of the sensor electrode on the visible side of the vehicle part is in particular advantageous here, because there is often only a small installation space for freely selectable positioning of the sensor electrode on the inner side (i.e. the side facing the vehicle body; this is alternatively also referred to as the rear side) of the vehicle part. Moreover, an electrical (measurement) field that is radiated to the outside from the sensor electrode disposed on the visible side is not or is only slightly affected by any metal contained in the vehicle part, so that a high degree of measurement precision is enabled.

Preferably, the sensor electrode and the higher-level proximity sensor are used for the contactless detection of a command of a vehicle user. Such a command is in particular an adjustment command for an automatically adjustable vehicle part, such as for example a vehicle door—preferably the vehicle door (also referred to as a trunk lid or trunk door) that is arranged for closing the trunk. In this case, the proximity sensor is in particular implemented as part of a motion-sensitive actuating device for said vehicle door. The actuating device is in this case advantageously arranged to detect the adjustment command of the vehicle user using the measurement signal output by the proximity sensor—which normally represents an approach or a predetermined operating event. In this case, the sensor electrode is preferably visually separated from the vehicle part, so that the vehicle user can advantageously detect the sensor electrode position without additional (visual) information.

So that in particular a movement of the vehicle user relative to the vehicle part can be accurately detected by means of the proximity sensor (and the actuating device), said proximity sensor advantageously comprises two sensor electrodes, which are disposed on the visible side of the vehicle part as described above. In particular, in this case the two sensor electrodes are each implemented as oblong (i.e. with a length that is larger compared to the width thereof) and are oriented parallel to each other. In this case the two sensor electrodes are also preferably oriented with the longitudinal extent thereof transverse to the vehicle's vertical direction when in the proper installation state, and thus extend in the lateral direction of the vehicle.

In a preferred embodiment, the sensor electrode, or in particular both sensor electrodes is/are embedded—preferably flush—in the visible surface of the vehicle part. In a simple embodiment, the or both sensor electrodes is/are introduced into complementary depressions of the vehicle part and for example glued and possibly then coated with a coat of lacquer. Alternatively, it is also conceivable within the scope of the invention that the one or both sensor electrodes is/are accommodated in a supporting element—in particular of a different color from the vehicle part for visual distinguishability—and fixed in the complementary depressions. Within the scope of the invention, such a supporting element can be a plastic part, into which the sensor electrode is introduced or which envelops the sensor electrode.

In a preferred embodiment, the sensor electrode, or in particular both sensor electrodes are each accommodated in a respective sensor holder. The respective sensor holder is in particular visibly (i.e. visually separately) on the visible surface of the vehicle part. Within the scope of the invention, it is thereby conceivable that the sensor holder is fitted onto the vehicle part for example by means of a clip connection, is glued on or is fixed by means of screws. It is thereby also conceivable within the scope of the invention that both sensor electrodes are accommodated in a common sensor holder. The sensor electrodes are inserted into the (respective) sensor holder in a simple implementation, and are in particular held in position by the attachment of the sensor holder to the vehicle part. Alternatively, the sensor electrodes (preferably injection molding technology) are integrated within the sensor holder or deposited as a metal coating on the rear side of the sensor holder. As a result of the sensor holder being on the vehicle part, the vehicle part can be manufactured particularly simply—in particular only through holes are to be provided for a cable for the respective sensor electrode and preferably for an at least partly positive-locking connection of the sensor holder.

In order to enable unrestricted propagation of the electric field around the sensor electrodes towards the exterior of the vehicle, the or each sensor holder is advantageously made of preferably soft plastic, in particular an elastomer. The sensor holders are thereby preferably designed to be visible on the vehicle part as “rubber beading” (and hence can also be touched).

In a preferred embodiment, the vehicle part is an underrun guard that is made of metal (and is consequently electrically conductive), in particular a rear underrun guard. Such underrun guards are conventionally used in all-terrain vehicles (also off-road vehicles) or so-called Sports Utility Vehicles (abbreviated to SUV), in order to prevent damage to the underneath and/or the front bumper or rear bumper when driving over obstacles when driving off-road. By attaching the sensor electrodes or the sensor holder supporting the same to the visible side of the underrun guard, a movement beneath the vehicle or the underrun guard can also be detected by means of the sensor electrodes because the metal of the underrun guard is disposed outside the electric (measurement) field of the sensor electrodes (the field is therefore not shielded). A distance of for example 2 to 10 mm from the respective sensor electrode to the metal underrun guard is preferably determined by means of the respective sensor holder. Moreover, a visual impression matching the “sporty” overall appearance of the off-road vehicle is achieved for the vehicle user by the sensor holder (or possibly the two sensor holders) preferably produced as rubber beading.

In an alternative embodiment, the vehicle part forms a bumper, in particular a rear bumper. In particular in this case, the sensor electrodes are preferably embedded in the bumper in order to achieve a smooth outer vehicle skin.

The vehicle part with the sensor electrode or electrodes (as well as possibly with the associated sensor holder) preferably forms a pre-assembled unit, which is mounted on the vehicle as a cohesive component during the assembly of the vehicle, wherein for attaching the vehicle part to the vehicle, preferably only the sensor electrodes have to be additionally contacted with a control and/or analysis unit.

The (motor) vehicle according to the invention comprises the vehicle part of the type described above, which is disposed in the exterior area of the vehicle. The vehicle is preferably an off-road vehicle or a SUV.

Exemplary embodiments of the invention are described in detail below using a drawing. In the figures.

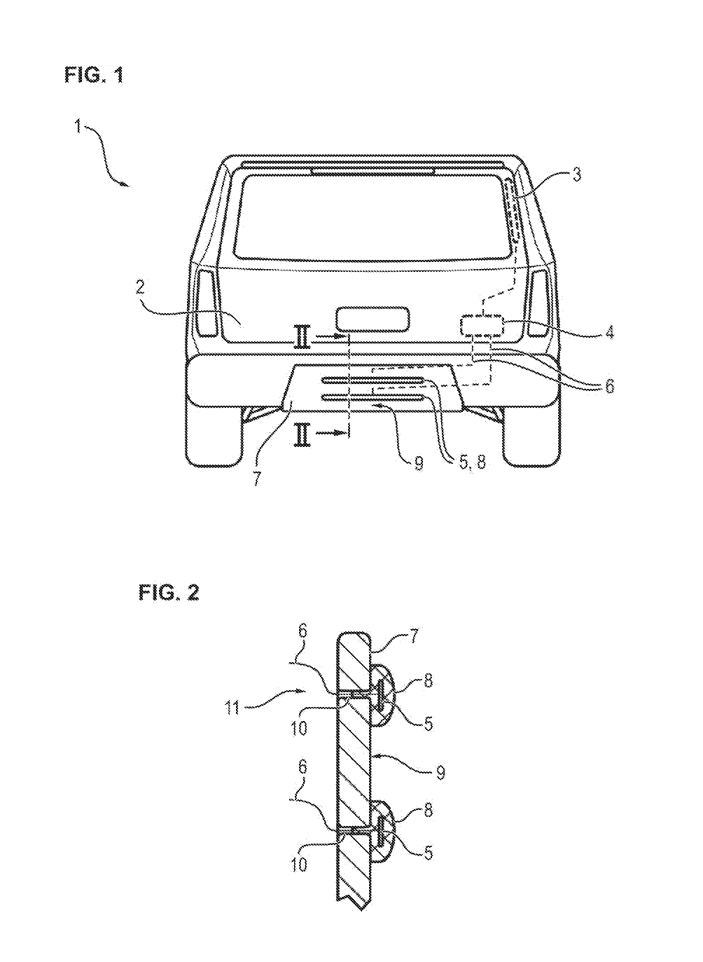

FIG. 1 shows the rear of a motor vehicle with a vehicle part supporting the two sensor electrodes in a schematic representation,

FIG. 2 shows the vehicle part with the sensor electrodes in a schematic section II-II according to FIG. 1, and

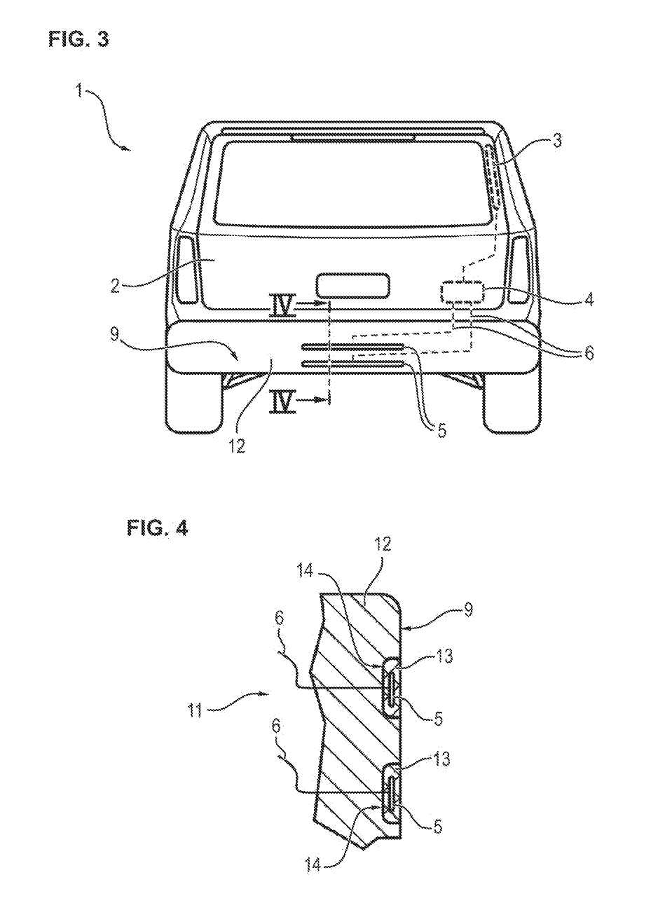

FIGS. 3 and 4 show in a view according to FIG. 1 or FIG. 2 an alternative exemplary embodiment of the vehicle part.

Mutually corresponding parts are always given the same reference characters in all figures.

In FIG. 1a (motor) vehicle 1 is represented in a view of the rear thereof. The vehicle 1 is a SUV. A trunk disposed in the interior of the vehicle 1 can be reversibly closed by a vehicle door (here the trunk lid 2). The trunk lid 2 can be automatically adjusted between a (not shown in detail) open position and a closed position that is shown in FIG. 1. For this the vehicle 1 comprises an actuating device with a (flap) actuating motor 3, which is implemented as a spindle motor and that is hinged in the region of the trunk lid 2 hinges. The actuating device comprises a control unit 4, by means of which the actuating motor 3 is actuated during operation.

The control unit 4 is arranged and provided to contactlessly detect a tail gate control command of a vehicle user and thereupon to open or close the trunk lid 2. For this purpose, a capacitive proximity sensor is integrated within the control unit 4, by means of which an approach by the vehicle user to the vehicle 1 is detected and a movement is detected from the time profile of the approach. The detected movement, specifically the measurement signal corresponding to the same, is compared with a stored reference signal by the control unit 4. If there is sufficient agreement, the control unit 4 assesses the detected movement as a flap control command and then adjusts the trunk lid 2. For detecting the displacement, the proximity sensor or the control unit 4 has a signal transfer coupling to two sensor electrodes 5 by means of respective signal lines 6. Whether the vehicle user is authorized to adjust the trunk lid 2 is determined by whether a (authorization) signal of a radio key associated with the vehicle 1 is received by a corresponding on-board system of the vehicle 1.

The two sensor electrodes 5 are fitted to the vehicle 1 as part of a vehicle part, specifically of an underrun guard 7. The underrun guard 7 is made of metal (sheet). In order to avoid influencing, in particular grounding, the sensor electrodes 5 by the underrun guard 7, the two sensor electrodes 5 are incorporated in a sensor holder 8 that is made of an elastomer so as to be electrically isolated (i.e. molded with the elastomer). Furthermore, in order to prevent shielding by the underrun guard 7 of the electrical measurement field that is radiated by the sensor electrodes 5 during operation, the sensor electrodes 5 with the respective sensor holder 8 thereof are mounted on an outward-facing visible surface 9 of the underrun guard 7 (see FIG. 2). The respective measurement field can thereby propagate unhindered to the exterior of the underrun guard 7 or of the vehicle 1. Moreover, bores 10 are incorporated in the underrun guard 7, in which the sensor holders 8 are held by positive locking and through which the signal lines 6 are led to the rear side 11 the underrun guard 7. Further, the sensor holders 8 form “rubber beads” that are parallel to each other, that extend in the lateral direction of the vehicle and that indicate to the vehicle user the position of the sensor electrodes 5, so that issuing the flap positioning command is facilitated. In addition, the rubber beads also contribute to the sporty, bulky appearance of the SUV.

In an alternative exemplary embodiment according to FIGS. 3 and 4, the vehicle part supporting the sensor electrodes 5 is implemented as a (rear) bumper 12. In this case, the sensor electrodes 5 are embedded flush in the visual surface 9. The sensor electrodes 5 are hereby injected into a supporting material 13, which in turn is inserted into the bumper 12 in complementary depressions 14. The supporting material 13 is colored differently than the bumper 12, so that the position of the sensor electrodes 5 can be simply detected. In this embodiment, the bumper 12 can also comprise metal components (for example stiffening structures), without adversely affecting the measurement field of the sensor electrodes 5) that is directed towards the exterior.

In both exemplary embodiments, the sensor electrodes 5 are optionally oriented differently. Thus, in particular the lower of the two sensor electrodes 5 is preferably oriented downwards, so that it detects approaches and operating events in a detection space disposed beneath the underrun guard 7 or bumper 12. The upper of the two sensor electrodes 5 is by contrast preferably at least approximately oriented horizontally, so that it detects approaches and operating events at about the same height as said sensor electrode 5.

In a further implementation of the invention, the sensor electrodes 5 are disposed together with the surrounding sensor holder 8 or supporting material 13 in oblong slots of the underrun guard 7 or bumper 12. The sensor holder 8 and the supporting material l3 are hereby broadened on the rear side of the underrun guard 7 or bumper 12 (which is not externally visible), so that the sensor holders 8 or the supporting material 13 are secured against detachment by undercutting the underrun guard 7 or bumper 12. The slots introduced into the underrun guard 7 or bumper 12 can hereby be widened in steps or continuously, in particular on the rear side, to accommodate the undercut.

The object of the invention is not limited to the exemplary embodiments described above. Rather, further embodiments of the invention can be derived by the person skilled in the art from the description above. In particular, individual features of the invention and the configuration variants thereof that were described using the various exemplary embodiments can also be combined with each other in different ways.

Reference Character List

1 Motor vehicle

2 Tail gate

3 Flap positioning motor

4 Control unit

5 Sensor electrode

6 Signal line

7 Underrun guard

8 Sensor mounting

9 Visible surface

10 Bore

11 Rear side

12 Rear bumper

13 Supporting material

14 Depression

1-8. (canceled)

9. A vehicle part for the exterior of a motor vehicle, the vehicle part comprising:
at least one sensor electrode of a capacitive proximity sensor, said at least one sensor electrode being disposed on a visible side of the vehicle part;
a sensor holder accommodating said at least one sensor electrode, said sensor holder being disposed on a visible surface of the vehicle part; and
the vehicle part forming an underrun guard made of metal.

10. The vehicle part according to claim 9, wherein said at least one sensor electrode is one of two sensor electrodes of the proximity sensor, said sensor electrodes having an oblong form with a length being a multiple of a width thereof and said sensor electrodes extending parallel to one another.

11. The vehicle part according to claim 10, wherein each of said two sensor electrodes is accommodated in a respective said sensor holder.

12. The vehicle part according to claim 11, wherein each said sensor holder is made of a soft plastic.

13. The vehicle part according to claim 12, wherein said soft plastic is an elastomer.

14. The vehicle part according to claim 9, wherein said sensor holder is made of soft plastic being an elastomer.

15. The vehicle part according to claim 9, wherein the underrun guard of metal is a rear underrun guard.

16. A motor vehicle, comprising a vehicle part according to claim 7.

17. An underrun guard assembly of a motor vehicle, the assembly comprising:
an underrun guard formed of metal, said underrun guard having an exposed side, upon being mounted on the motor vehicle, with a visible surface;
a sensor holder disposed on the visible surface of said underrun guard;
at least one sensor electrode of a capacitive proximity sensor, said at least one sensor electrode being disposed in said sensor holder on the visible surface and being electrically insulated from said underrun guard.

18. The assembly according to claim 17, wherein said at least one sensor electrode is one of two sensor electrodes of the proximity sensor, said sensor electrodes having an oblong form with a length being a multiple of a width thereof, said sensor electrodes extending parallel to one another, and each being disposed in a separate said sensor holder (8).
